(19) United States
(12) Patent Application Publication
(10) Pub. No.: US 2024/0260251 A1
(43) Pub. Date: Aug. 1, 2024

(54) Memory Circuitry And Methods Used In Forming Memory Circuitry

(71) Applicant: Micron Technology, Inc., Boise, ID (US)

(72) Inventors: Dong Wan Kim, Boise, ID (US); Russell A. Benson, Boise, ID (US); Byung Yoon Kim, Boise, ID (US)

(73) Assignee: Micron Technology, Inc., Boise, ID (US)

(21) Appl. No.: 18/419,808

(22) Filed: Jan. 23, 2024

Related U.S. Application Data
(60) Provisional application No. 63/441,378, filed on Jan. 26, 2023.

(51) Int. Cl. H10B 12/00

(52) U.S. Cl. CPC H10B 12/053; H10B 12/315; H10B 12/34

(57) ABSTRACT

A method used in forming memory circuitry comprises forming transistors individually comprising one source/drain region and another source/drain region. A channel region is between the one and the another source/drain regions. A conductive gate is operatively proximate the channel region. The conductive gate comprises part of one of a plurality of conductive-gate lines in a substrate. Lines of conductive material are formed directly above and directly against individual of the one and another source/drain regions. Individual of the lines of the conductive material are between immediately-laterally-adjacent of the conductive-gate lines. The lines of the conductive material directly above the another source/drain regions are etched through to form islands of the conductive material that are individually directly above and directly against the individual one source/drain regions. Storage elements are formed that are individually electrically coupled to individual of the one source/drain regions through individual of the islands of the conductive material. Other embodiments, including structure, are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The digitlines may conductively interconnect memory cells along columns of the array, and the access lines may conductively interconnect memory cells along rows of the array. Each memory cell may be uniquely addressed through the combination of a digitline and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

A capacitor is one type of electronic component that may be used in a memory cell. A capacitor has two electrical conductors separated by electrically insulating material. Energy as an electric field may be electrostatically stored within such material. Depending on composition of the insulator material, that stored field will be volatile or non-volatile. For example, a capacitor insulator material including only SiO₂ will be volatile. One type of non-volatile capacitor is a ferroelectric capacitor which has ferroelectric material as at least part of the insulating material. Ferroelectric materials are characterized by having two stable polarized states and thereby can comprise programmable material of a capacitor and/or memory cell. The polarization state of the ferroelectric material can be changed by application of suitable programming voltages and remains after removal of the programming voltage (at least for a time). Each polarization state has a different charge-stored capacitance from the other, and which ideally can be used to write (i.e., store) and read a memory state without reversing the polarization state until such is desired to be reversed. Less desirable, in some memory having ferroelectric capacitors the act of reading the memory state can reverse the polarization. Accordingly, upon determining the polarization state, a re-write of the memory cell is conducted to put the memory cell into the pre-read state immediately after its determination. Regardless, a memory cell incorporating a ferroelectric capacitor ideally is non-volatile due to the bi-stable characteristics of the ferroelectric material that forms a part of the capacitor. Other programmable materials may be used as a capacitor insulator to render capacitors non-volatile.

A field effect transistor is another type of electronic component that may be used in a memory cell. These transistors comprise a pair of conductive source/drain regions having a semiconductive channel region there-between. A conductive gate is adjacent the channel region and separated there-from by a thin gate insulator. Application of a suitable voltage to the gate allows current to flow from one of the source/drain regions to the other through the channel region. When the voltage is removed from the gate, current is largely prevented from flowing through the channel region. Field effect transistors may also include additional structure, for example a reversibly programmable charge-storage region as part of the gate construction between the gate insulator and the conductive gate. Regardless, the gate insulator may be programmable, for example being ferroelectric.

### BRIEF DESCRIPTION OF THE DRAWINGS

FIGS. 1-6 are diagrammatic cross-sectional views of a portion of a DRAM construction in fabrication in accordance with some embodiments of the invention.

FIGS. 7-25 are diagrammatic sequential sectional views of the construction of FIGS. 1-6 in subsequent processing in accordance with some embodiments of the invention.

### DETAILED DESCRIPTION OF EXAMPLE EMBODIMENTS

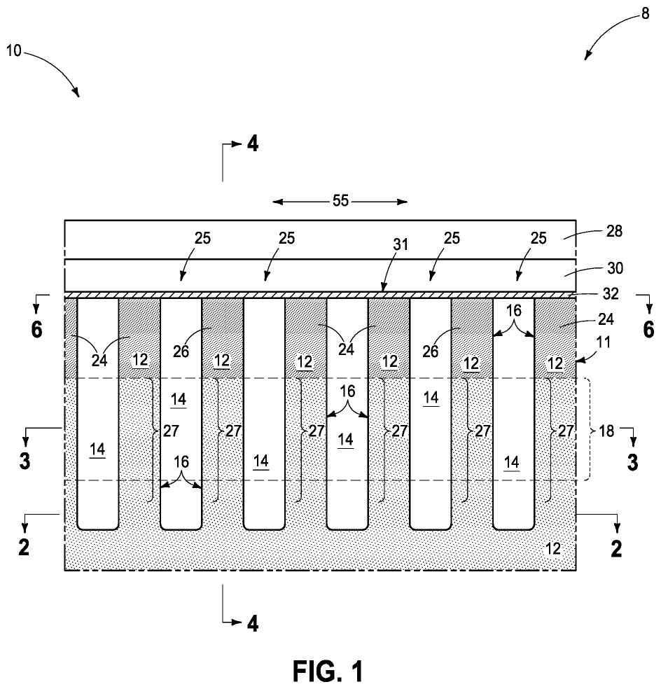

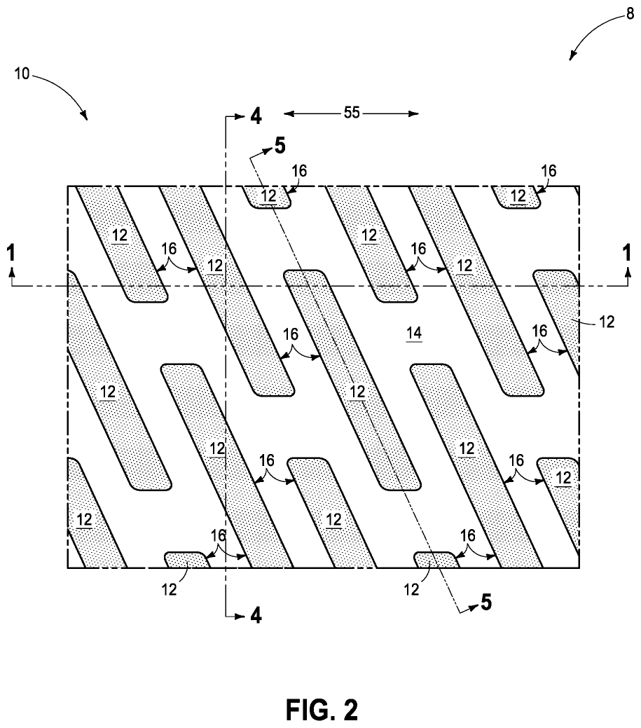

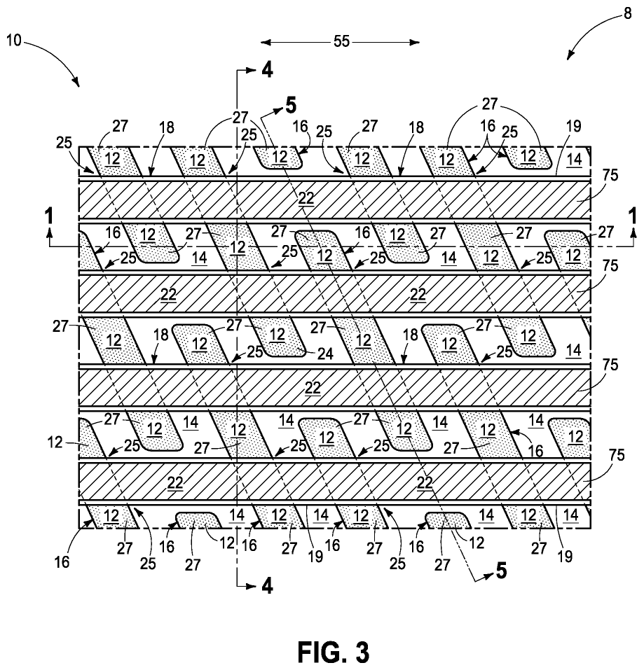

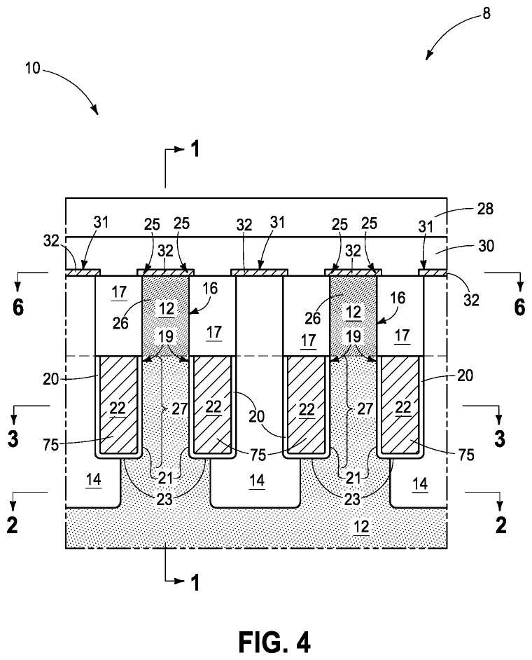

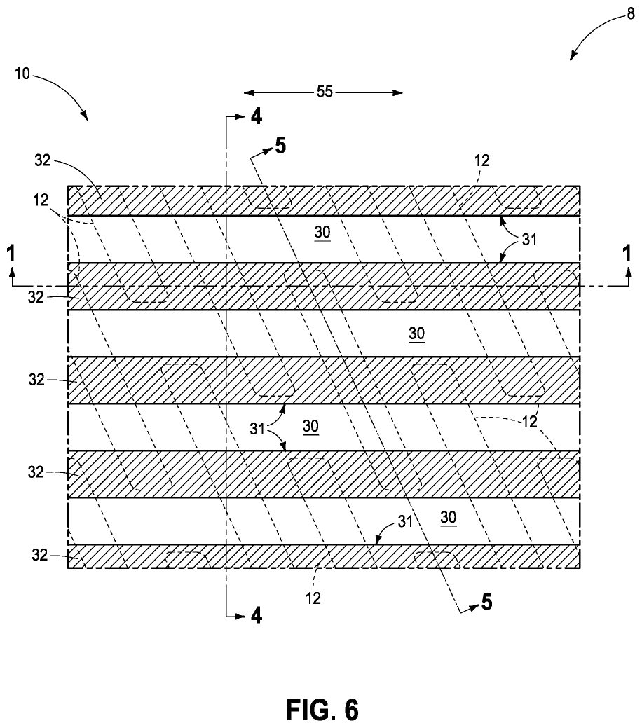

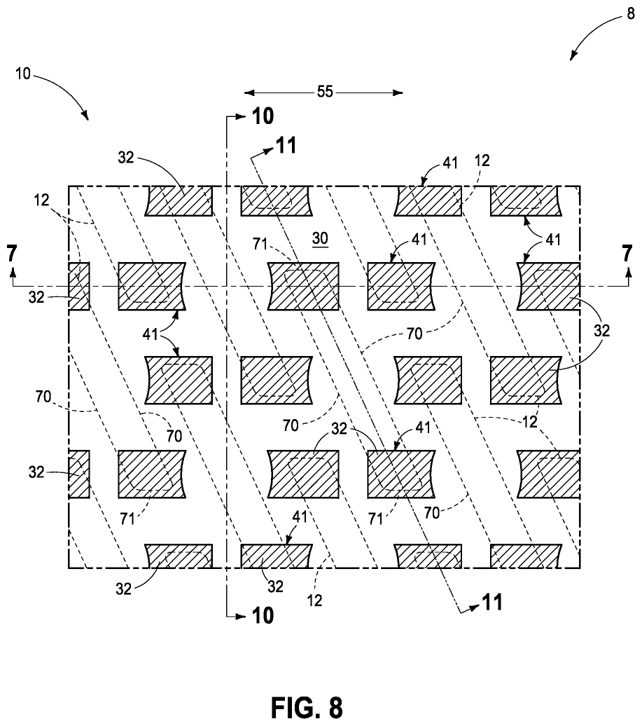

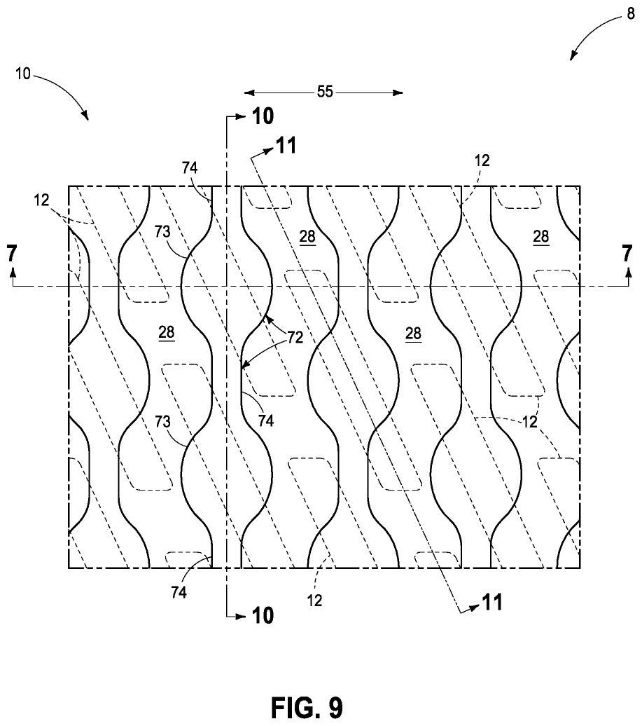

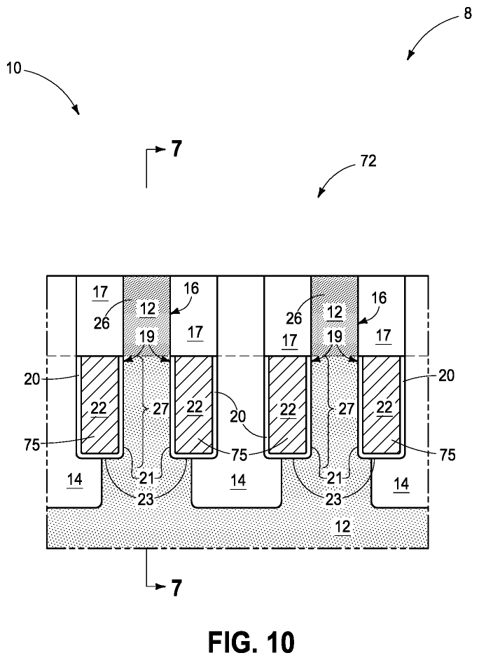

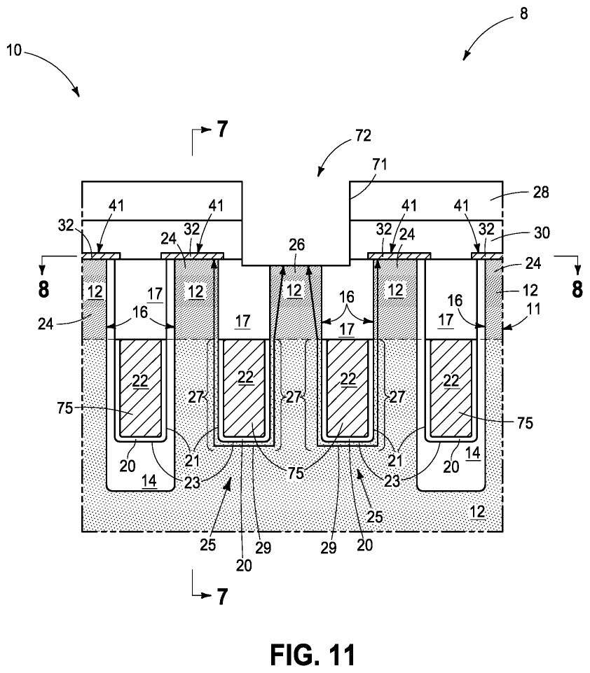

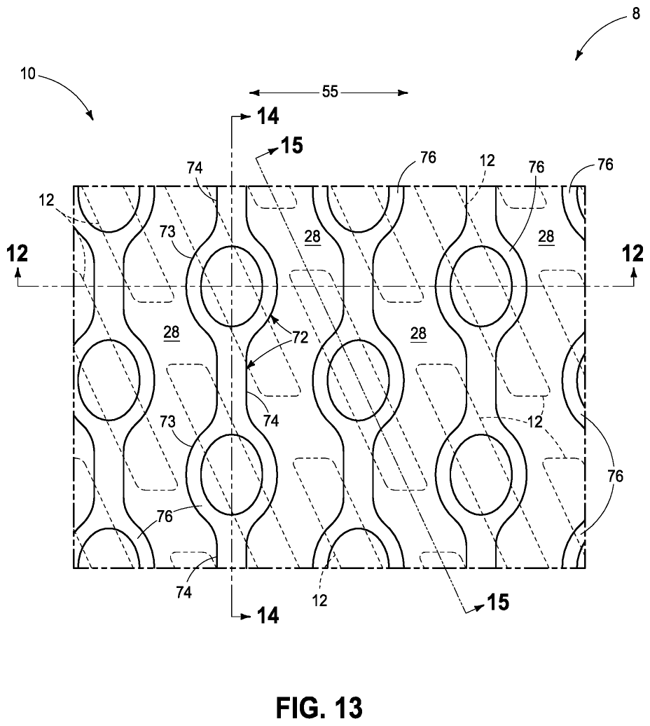

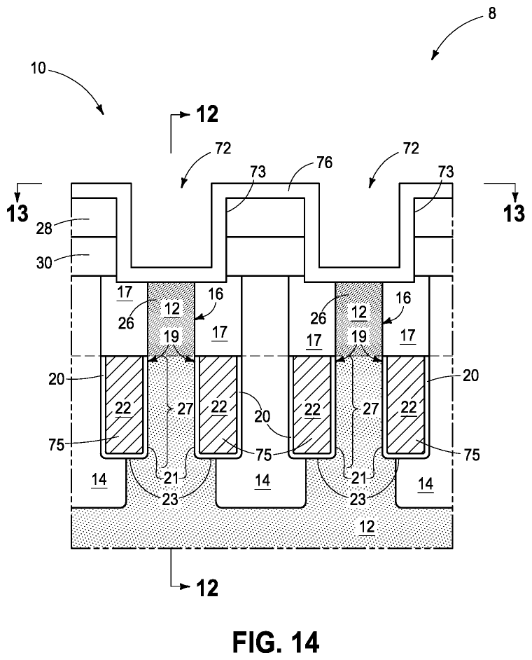

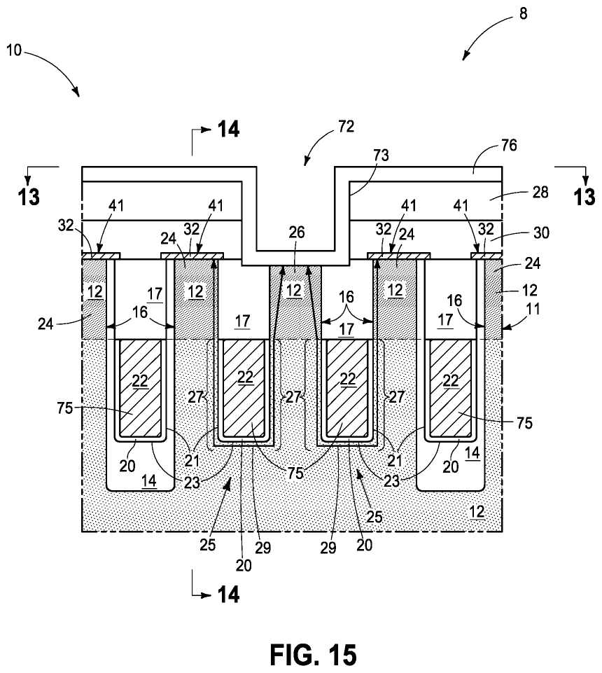

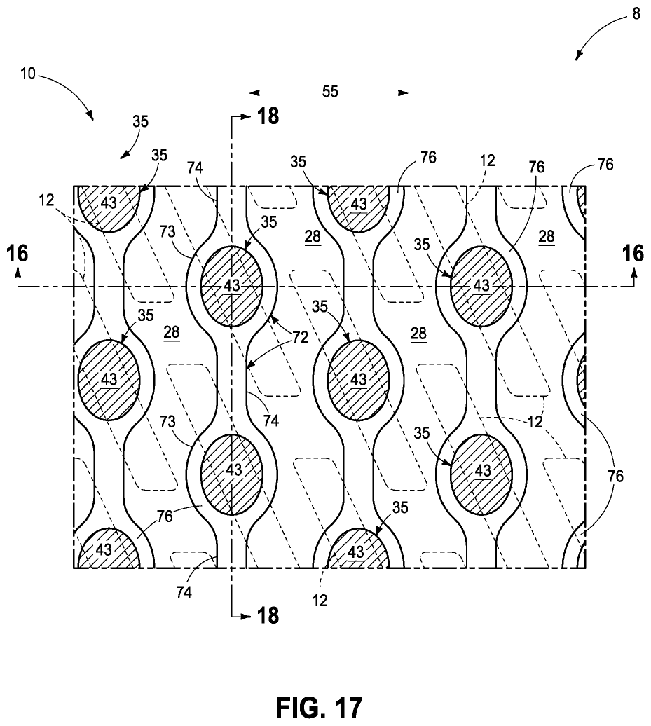

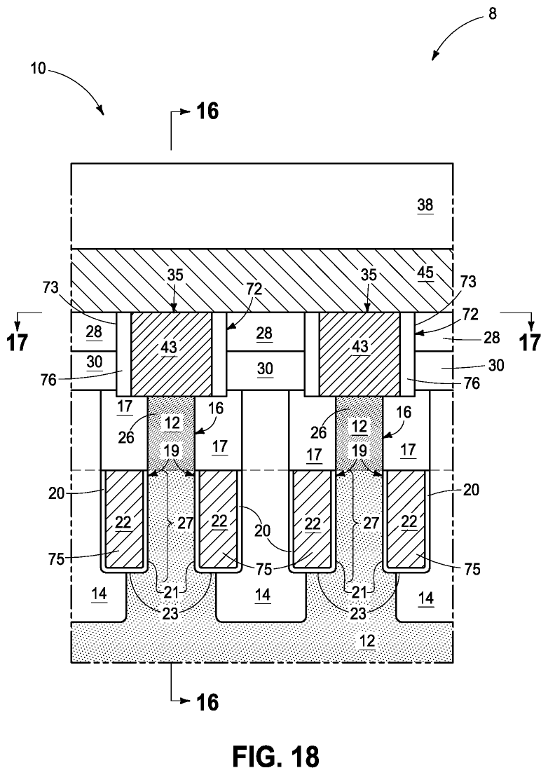

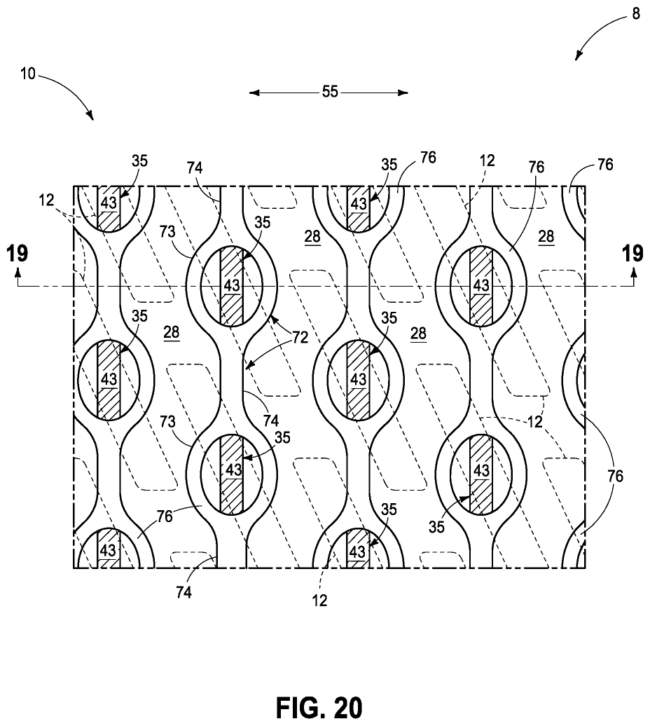

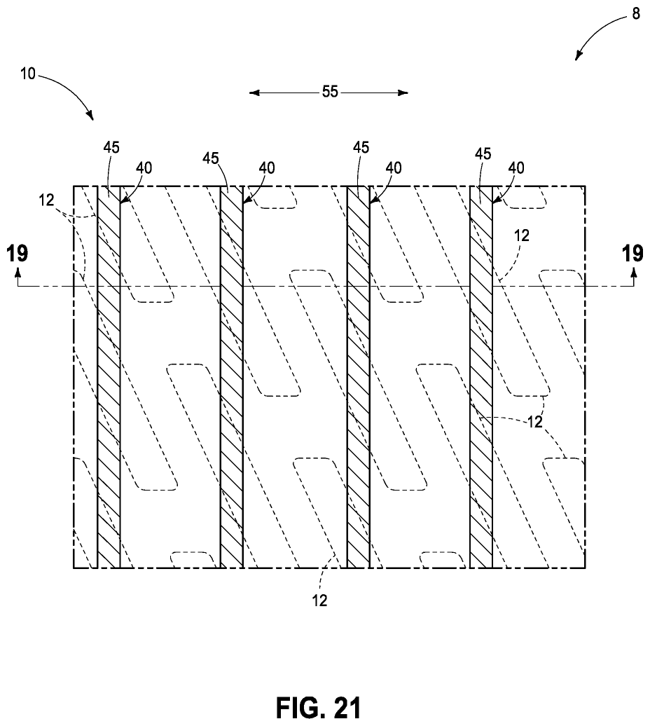

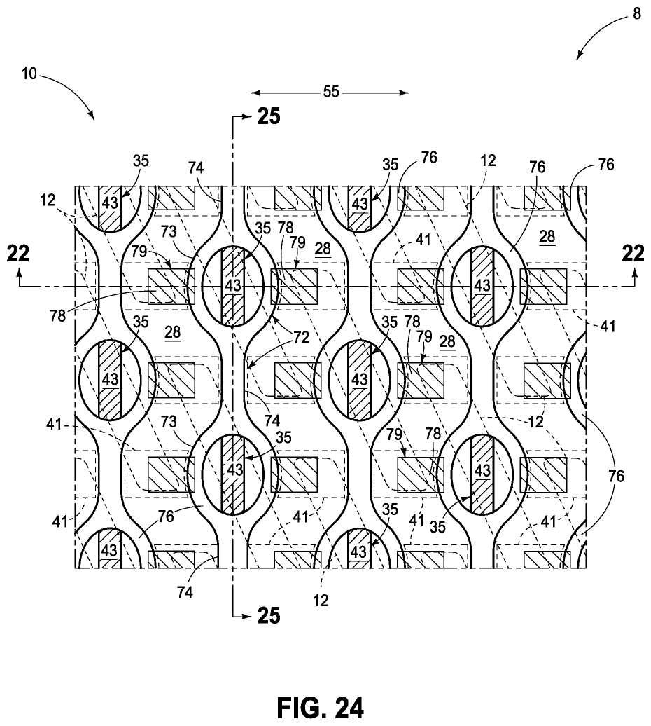

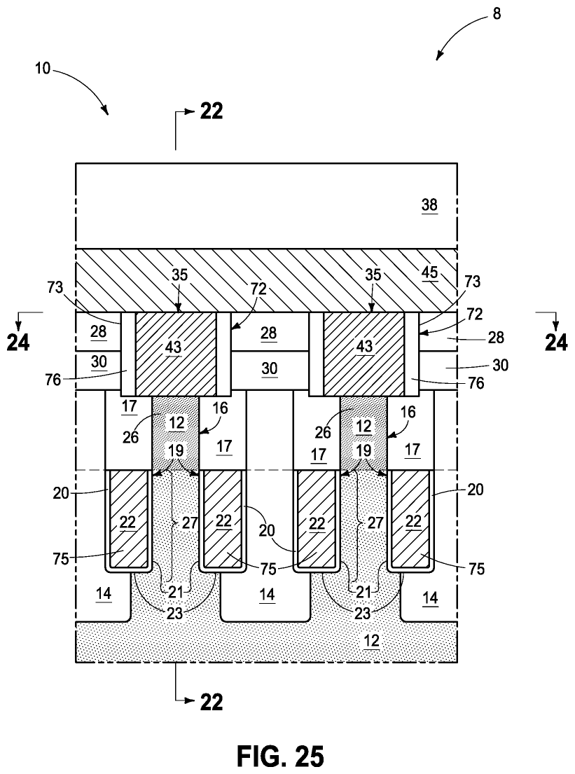

Embodiments of the invention encompass memory circuitry, such as DRAM, and methods used in forming memory circuitry, such as a DRAM. First example method embodiments are described with reference to FIGS. 1-25.

Referring to FIGS. 1-6, an example fragment of a substrate construction 8 comprising an array or array area 10 has been fabricated relative to a base substrate 11. Substrate 11 may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIGS. 1-6-depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array.

Base substrate 11 comprises semiconductive material 12 (e.g., appropriately and variously doped monocrystalline and/or polycrystalline silicon, Ge, SiGe, GaAs, and/or other existing or future-developed semiconductive material), trench isolation regions 14 (e.g., silicon nitride atop silicon dioxide), and active area regions 16 comprising suitably and variously-doped semiconductive material 12. Construction 8 comprises transistors 25 individually comprising one source/drain region 24 and another source/drain region 26, a channel region 27 between the one and the another source/drain regions, and a conductive gate 22 (e.g., conductively-doped semiconductor material and/or metal material, including for example elemental W, Ru, and/or Mo) operatively proximate channel region 27 (e.g., a gate insulator 20 being between the conductive gate 22 and channel region 27, for example silicon dioxide and/or silicon nitride). Conductive gate 22 comprises part of one of a plurality of conductive-gate lines 75 in substrate 11 and that extend along a row direction 55. Transistors 25 are shown as being recessed access devices, with example construction 8 showing such recessed access devices grouped in individual pairs of such devices. Individual recessed access devices/transistors 25 include a buried access line construction 18, for example that is within a trench 19 in semiconductive material 12. Constructions 18 comprise conductive gate 22. Gate insulator 20 is along sidewalls 21 and a base 23 of individual trenches 19 between conductive gate 22 and semiconductive material 12. Insulator material 17 (e.g., silicon dioxide and/or silicon nitride) is within trenches 19 above materials 20 and 22. One source/drain region 24 and another source/drain region 26 are in upper portions of semiconductive material 12 on opposing sides of individual trenches 19 (e.g., regions 24, 26 being laterally-outward of and higher than access line constructions 18). Each of source/drain regions 24, 26 has at least a part thereof having a conductivity-increasing dopant therein that is of maximum concentration of such conductivity-increasing dopant within the respective source/drain region 24, 26, for example to render such part to be conductive (e.g., having a maximum dopant concentration of at least 10¹⁹ atoms/cm³). Accordingly, all or only a part of each source/drain region 24, 26 may have such maximum concentration of conductivity-increasing dopant. Source/drain regions 24 and/or 26 may include other doped regions (not shown), for example halo regions, LDD regions, etc.

In the example embodiment, one of the source/drain regions (e.g., another source/drain region 26) of the pair of source/drain regions in individual of the pairs of transistors 25 is laterally between conductive gates 22 and is shared by the pair of devices 25. Others of the source/drain regions (e.g., one source/drain region 24) of the pair of source/drain regions are not shared by the pair of transistors 25. Thus, in the example embodiment, each active area region 16 comprises two transistors 25 (e.g., one pair of transistors 25), with each sharing a central source/drain region 26.

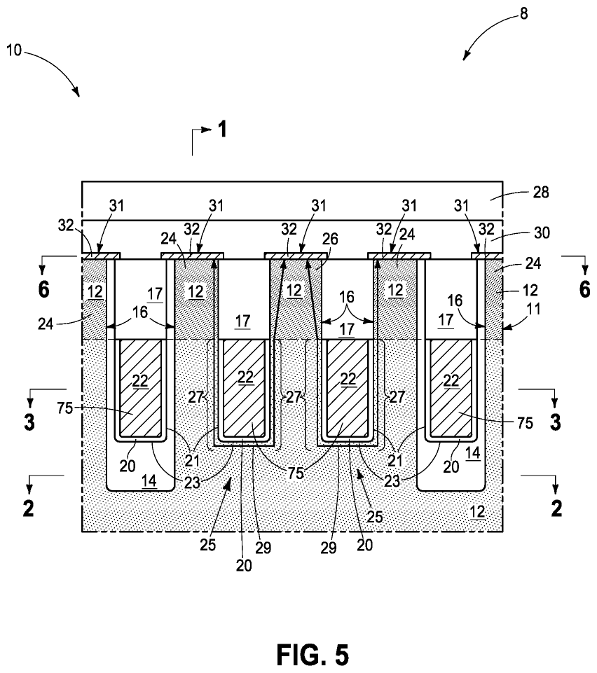

Example channel region 27 is in semiconductive material 12 below pair of source/drain regions 24, 26 along trench sidewalls 21 and around trench base 23. Channel region 27 may be undoped or may be suitably doped with a conductivity-increasing dopant likely of the opposite conductivity-type of the dopant in source/drain regions 24, 26. When suitable voltage is applied to gate material 22 of an access line construction 18, a conductive channel forms (e.g., along a channel current-flow line/path 29 [FIG. 5]) within channel region 27 proximate gate insulator 20 such that current is capable of flowing between a pair of source/drain regions 24 and 26 under the access line construction 18 within an individual active area region 16. Stippling is diagrammatically shown to indicate primary conductivity-modifying dopant concentration (regardless of type), with denser stippling indicating greater dopant concentration and lighter stippling indicating lower dopant concentration. Conductivity-modifying dopant may be, and would likely be, in other portions of material 12 as shown. Only two different stippling densities are shown in material 12 for convenience, and additional dopant concentrations may be used, and constant dopant concentration is not required in any region.

Lines 31 of conductive material 32 (e.g., conductive metal material and/or conductively-doped semiconductive material) have been formed along row direction 55 directly above and directly against individual of the one and another source/drain regions 24, 26, with individual lines 31 being between immediately-laterally-adjacent conductive-gate lines 75, and which may (as shown) or may not (not shown) vertically-overlap therewith. In some embodiments, conductive material 32 may be considered and referred to as first conductive material 32. In one embodiment, insulating material 30 (e.g., silicon dioxide) and insulating material 28 (e.g., silicon nitride) have been formed above lines 31. Lines 31 may be formed commensurate with forming trenches 19 (in a same/single/common masking step), thereby not requiring separate masking steps in forming trenches 19 and lines 31.

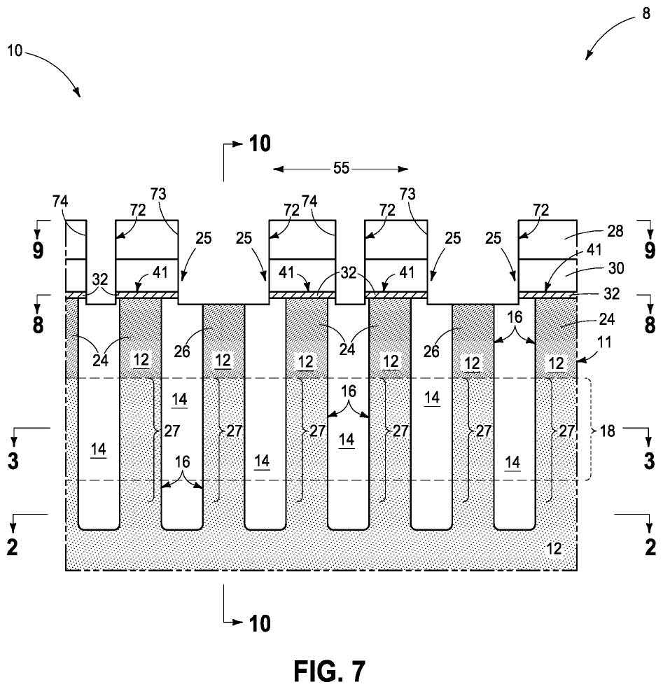

Referring to FIGS. 7-11, etching has been conducted through lines 31 of first conductive material 32 (and insulating materials 28, 30 if present) directly above another source/drain regions 26 to form islands 41 of first conductive material 32 that are individually directly above and directly against individual one source/drain regions 24. In one embodiment, individual islands 41 extend laterally-outward beyond individual one source/drain regions, in one such embodiment from at least one side 70, from both sides 70, and/or from a longitudinal end 71 of individual one source/drain regions 24. In one embodiment, such etching forms trenches 72 (e.g., in insulating materials 28, 30) that are individually directly above a plurality of another source/drain regions 26 and above and crossing over the plurality of conductive-gate lines 75. In one embodiment and as shown, individual trenches 72 are widest directly above another source/drain regions 72 (e.g., having widest portions 73) than between another source/drain regions 72 (e.g., having narrow portions 74). Regardless, in one embodiment, two photomasking steps are used to form longitudinal outlines of individual trenches 72 (e.g., a first photomask that forms the longitudinal outlines of narrow portions 74 and a second photomask that forms longitudinal outlines of widest portions 73; the first photomask may have openings therein that are continuous, going through what-will-be widest portions 73 next).

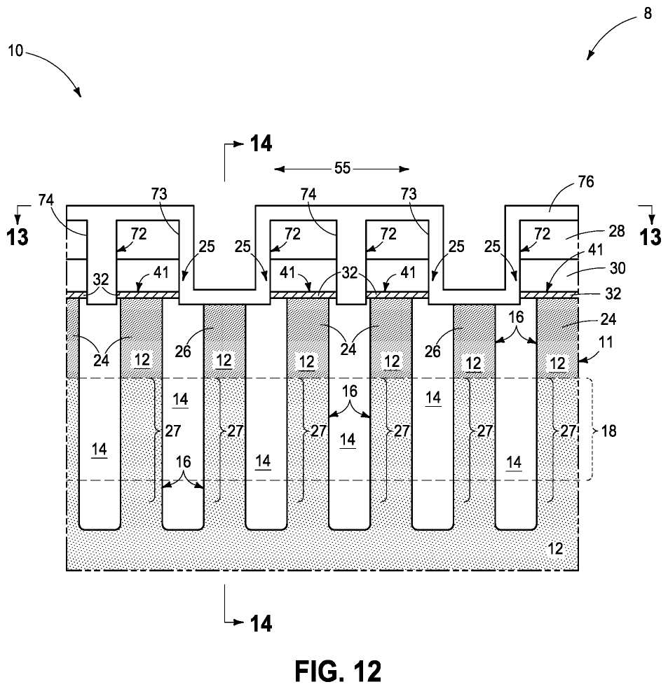

Referring to FIGS. 12-15, and in one embodiment, insulator material 76 (e.g., silicon dioxide and/or silicon nitride) has been formed in individual trenches 72 and that laterally-fills narrow portions 74 and does not laterally-fill widest portions 73.

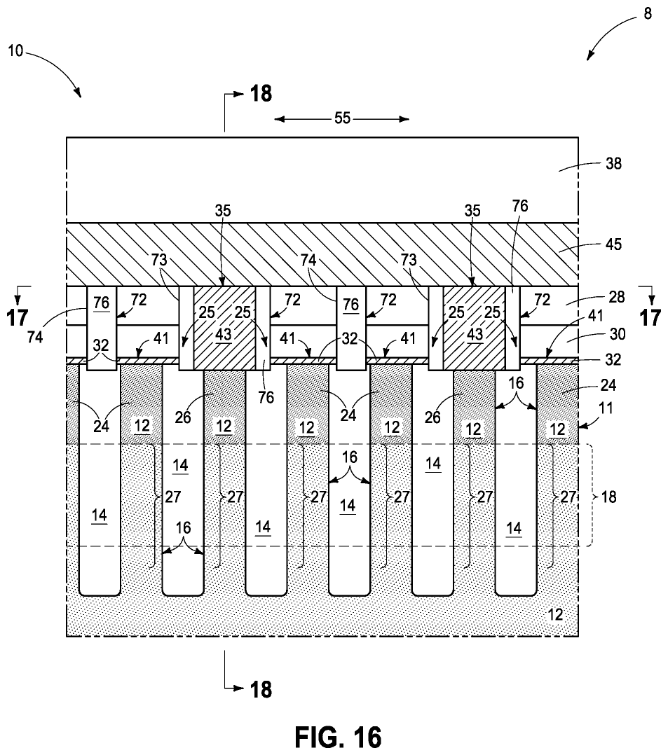

Referring to FIGS. 16-18, and in one embodiment, conductive material 43 has been formed in widest portions 73 thereby forming conducting vias 35 that are individually directly above and electrically coupled to individual another source/drain regions 26 and that will connect individual digitlines (not shown yet) to individual another source/drain regions 26. Thereafter, conducting material 45 (e.g., conductive metal material) has been formed directly above (e.g., directly against) conducting vias 35. Insulative material 38 (e.g., silicon dioxide and/or silicon nitride) has been formed above conducting material 45.

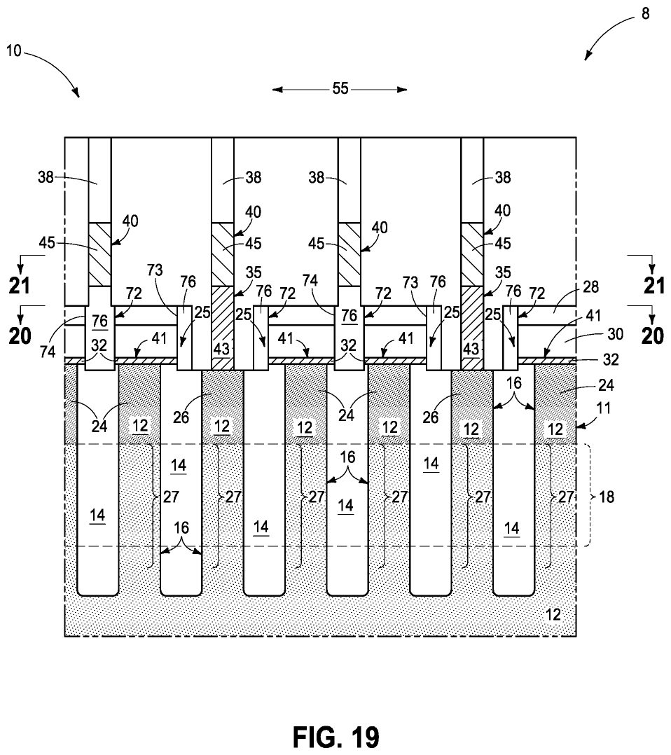

Referring to FIGS. 19-21, digitlines 40 (e.g., comprising conducting material 45) have been formed (e.g., by etching materials 38, 45, and 43) and that are individually electrically coupled to individual another source/drain regions 26 (e.g., directly electrically coupled; e.g., through conducting vias 35).

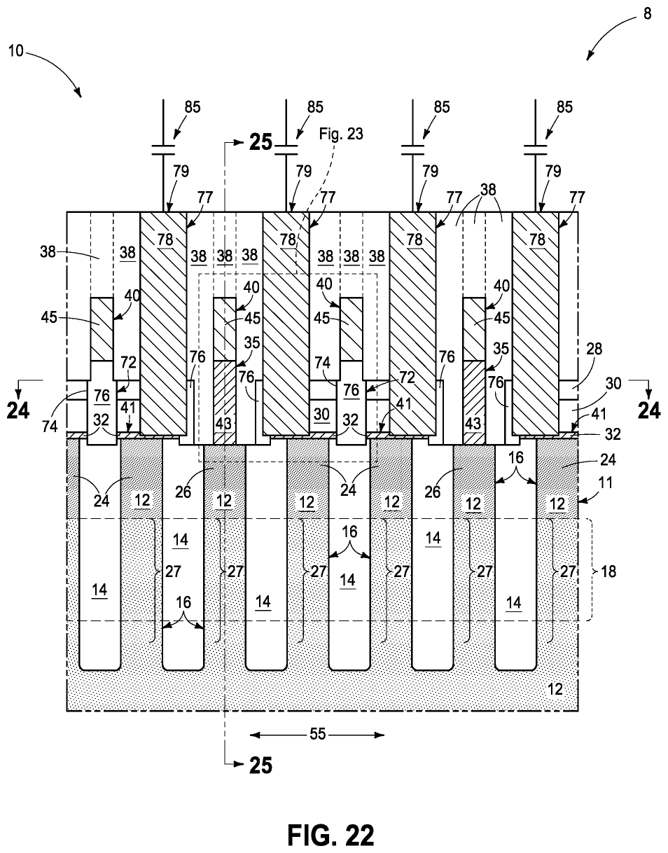

Referring to FIGS. 22-25, more insulative material 38 has been formed and contact openings 77 have been formed there-through to islands 41 (e.g., by etching using islands 41 as etch-stops/landing pads). One or more anisotropically-etched spacers (e.g., comprising silicon nitride and/or silicon dioxide) may be formed prior to or comprise part of insulative material 38 (not shown). Thereafter, second conductive material 78 of conductive vias 79 has been formed in contact openings 77 directly above and directly against islands 41 of first conductive material 32. Storage elements 85 (e.g., capacitors) are then formed and that are individually electrically coupled (e.g., directly electrically coupled) to individual of one source/drain regions 24 through second conductive material 78 of individual conductive vias 79 and individual islands 41 of first conductive material 32.

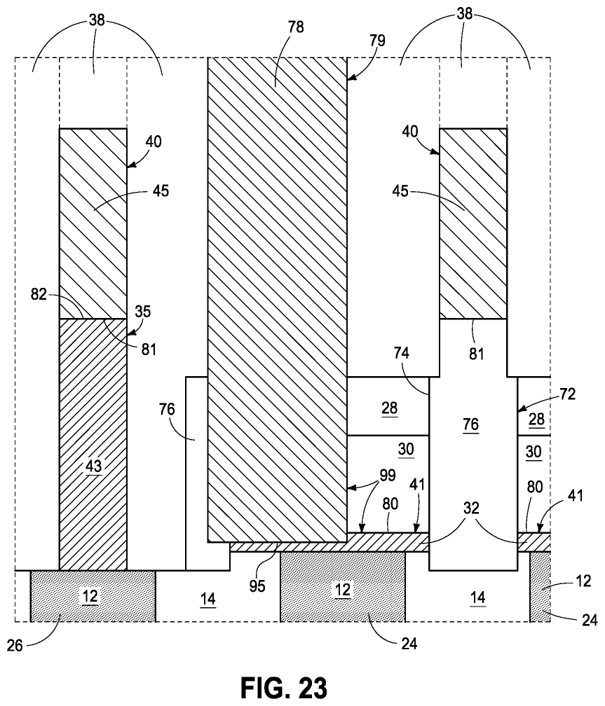

In some embodiments and as shown, second conductive material 78 extends downwardly into first conductive material 32, second conductive material 78 extends laterally-outward beyond first conductive material 32, and islands 41 of first conductive material 32 have a top 80 (FIG. 23) that is below a bottom 81 of digitlines 40 and below a top 82 of conducting vias 35.

In one embodiment, first conductive material 32 and second conductive material 78 are of the same composition relative one another and in another embodiment are of different compositions relative one another (e.g., having an interface 95 there-between [FIG. 23]). Interfaces herein may be continuous or may be discontinuous at some place(s) there-along. Interfaces will be continuous when the immediately-adjacent materials thereof are of different compositions relative one another. Interfaces may or may not be continuous when the immediately-adjacent materials thereof are of the same composition relative one another. For example, separate-in-time formed immediately-adjacent materials if of the same composition relative one another may nevertheless have a perceptible interface in a finished construction. Some of that interface may effectively disappear (i.e., not be perceptible) and some may remain perceptible whereby that interface is discontinuous in one or more locations longitudinally-there-along (e.g., as may occur by welding of the same-composition materials together due to subsequent heating during manufacture).

Any other attribute(s) or aspect(s) as shown and/or described herein with respect to other embodiments may be used in the embodiments shown and described with reference to the above embodiments.

In one embodiment, a method used in forming memory circuitry (e.g., 8) comprises forming transistors (e.g., 25) individually comprising one source/drain region (e.g., 24) and another source/drain region (e.g., 26). A channel region (e.g., 27) is between the one and the another source/drain regions. A conductive gate (e.g., 22) is operatively proximate the channel region. The conductive gate comprises part of one of a plurality of conductive-gate lines (e.g., 75) in a substrate (e.g., 11). Lines (e.g., 31) of conductive material (e.g., 32) are directly above and directly against individual of the one and another source/drain regions. Individual of the lines of the conductive material are between immediately-laterally-adjacent of the conductive-gate lines (i.e., there being no other conductive-gate line between those that are immediately-laterally-adjacent one another). Etching is conducted through the lines of the conductive material directly above the another source/drain regions to form islands (e.g., 41) of the conductive material that are individually directly above and directly against the individual one source/drain regions. Storage elements (e.g., 85) are formed that are individually electrically coupled to individual of the one source/drain regions through individual of the islands of the conductive material. Any other attribute(s) or aspect(s) as shown and/or described herein with respect to other embodiments may be used.

Forming and using islands 41 as shown and described herein may facilitate stopping of etching of contact openings 77 relative to one source/drain regions 24 better than in the absence of such islands.

Alternate embodiment constructions may result from method embodiments described above, or otherwise. Regardless, embodiments of the invention encompass memory arrays independent of method of manufacture. Nevertheless, such memory arrays may have any of the attributes as described herein in method embodiments. Likewise, the above-described method embodiments may incorporate, form, and/or have any of the attributes described with respect to device embodiments.

In one embodiment, memory circuitry (e.g., 8) comprises transistors (e.g., 25) individually comprising one source/drain region (e.g., 24) and another source/drain region (e.g., 26). A channel region (e.g., 27) is between the one and the another source/drain regions. A conductive gate (e.g., 22) is operatively proximate the channel region. Conducting vias (e.g., 35) are individually directly above and electrically coupled to individual of the another source/drain regions. Digitlines (e.g., 40) are individually above and directly electrically coupled to a plurality of the conducting vias. Conductive-via constructions (e.g., 99, FIG. 23) are individually directly above and directly against individual of the one source/drain regions. Individual of the conductive-via constructions comprise islands (e.g., 41) of first conductive material (e.g., 32) that are individually directly above and directly against the individual one source/drain regions. The islands of the first conductive material have a top (e.g., 80) that is below a bottom (e.g., 81) of the digitlines and below a top (e.g., 82) of the conducting vias. Individual of the conductive-via constructions also comprise second conductive material (e.g., 78) that is directly above and directly against the islands of the first conductive material. Storage elements (e.g., 85) are individually electrically coupled to the individual conductive-via construction. Any other attribute(s) or aspect(s) as shown and/or described herein with respect to other embodiments may be used.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 450 from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### CONCLUSION

In some embodiments, a method used in forming memory circuitry comprises forming transistors individually comprising one source/drain region and another source/drain region. A channel region is between the one and the another source/drain regions. A conductive gate is operatively proximate the channel region. The conductive gate comprises part of one of a plurality of conductive-gate lines in a substrate. Lines of conductive material are formed directly above and directly against individual of the one and another source/drain regions. Individual of the lines of the conductive material are between immediately-laterally-adjacent of the conductive-gate lines. The lines of the conductive material directly above the another source/drain regions are etched through to form islands of the conductive material that are individually directly above and directly against the individual one source/drain regions. Storage elements are formed that are individually electrically coupled to individual of the one source/drain regions through individual of the islands of the conductive material.

In some embodiments, a method used in forming memory circuitry comprises forming transistors individually comprising one source/drain region and another source/drain region. A channel region is between the one and the another source/drain regions. A conductive gate is operatively proximate the channel region. The conductive gate comprises part of one of a plurality of conductive-gate lines in a substrate and that extend along a row direction. Lines of first conductive material are formed along the row direction directly above and directly against individual of the one and another source/drain regions. Individual of the lines of the first conductive material are between immediately-laterally-adjacent of the conductive-gate lines. The lines of the first conductive material directly above the another source/drain regions are etched through to form islands of the first conductive material that are individually directly above and directly against the individual one source/drain regions. After the etching, digitlines are formed that are individually electrically coupled to individual of the another source/drain regions. After forming the digitlines, second conductive material of conductive vias is formed directly above and directly against the islands of the first conductive material. Storage elements are formed that are individually electrically coupled to individual of the one source/drain regions through the second conductive material of individual of the conductive vias and individual of the islands of the first conductive material.

In some embodiments, memory circuitry comprises transistors individually comprising one source/drain region and another source/drain region. A channel region is between the one and the another source/drain regions. A conductive gate is operatively proximate the channel region. Conducting vias are individually directly above and electrically coupled to individual of the another source/drain regions. Digitlines are individually above and directly electrically coupled to a plurality of the conducting vias. Conductive-via constructions are individually directly above and directly against individual of the one source/drain regions. Individual of the conductive-via constructions comprise islands of first conductive material that are individually directly above and directly against the individual one source/drain regions. The islands of the first conductive material have a top that is below a bottom of the digitlines and below a top of the conducting vias. Second conductive material is directly above and directly against the islands of the first conductive material. Storage elements are individually electrically coupled to the individual conductive-via construction.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry, comprising:
forming transistors individually comprising:
one source/drain region and another source/drain region;
a channel region between the one and the another source/drain regions; and
a conductive gate operatively proximate the channel region, the conductive gate comprising part of one of a plurality of conductive-gate lines in a substrate;
forming lines of conductive material directly above and directly against individual of the one and another source/drain regions, individual of the lines of the conductive material being between immediately-laterally-adjacent of the conductive-gate lines;
etching through the lines of the conductive material directly above the another source/drain regions to form islands of the conductive material that are individually directly above and directly against the individual one source/drain regions; and
forming storage elements that are individually electrically coupled to individual of the one source/drain regions through individual of the islands of the conductive material.

2. The method of claim 1 wherein the etching forms trenches that are individually directly above a plurality of the another source/drain regions and above and crossing over the plurality of conductive-gate lines.

3. The method of claim 2 wherein individual of the trenches are widest directly above the another source/drain regions than between the another source/drain regions.

4. The method of claim 3 comprising using two photomasking steps to form longitudinal outlines of the individual trenches.

5. The method of claim 3 comprising forming insulator material in the individual trenches that laterally-fills narrower portions of the individual trenches and does not laterally-fill widest portions of the trenches that are directly above the another source/drain regions.

6. The method of claim 1 wherein individual of the islands extend laterally-outward beyond the individual one source/drain regions.

7. The method of claim 1 wherein individual of the islands extend laterally-outward beyond the individual one source/drain regions on both sides of the individual one source/drain regions.

8. The method of claim 1 wherein individual of the islands extend laterally-outward beyond a longitudinal end of the individual one source/drain regions.

9. The method of claim 1 wherein individual of the islands extend laterally-outward beyond the individual one source/drain regions on both sides of the individual one source/drain regions and laterally-outward beyond a longitudinal end of the individual one source/drain regions.

10. A method used in forming memory circuitry, comprising:
forming transistors individually comprising:
one source/drain region and another source/drain region;
a channel region between the one and the another source/drain regions; and
a conductive gate operatively proximate the channel region, the conductive gate comprising part of one of a plurality of conductive-gate lines in a substrate and that extend along a row direction;
forming lines of first conductive material along the row direction directly above and directly against individual of the one and another source/drain regions, individual of the lines of the first conductive material being between immediately-laterally-adjacent of the conductive-gate lines;
etching through the lines of the first conductive material directly above the another source/drain regions to form islands of the first conductive material that are individually directly above and directly against the individual one source/drain regions;
after the etching, forming digitlines that are individually electrically coupled to individual of the another source/drain regions;
after forming the digitlines, forming second conductive material of conductive vias directly above and directly against the islands of the first conductive material; and
forming storage elements that are individually electrically coupled to individual of the one source/drain regions through the second conductive material of individual of the conductive vias and individual of the islands of the first conductive material.

11. The method of claim 10 wherein the first and second conductive materials are of the same composition relative one another.

12. The method of claim 10 wherein the first and second conductive materials are of different compositions relative one another.

13. The method of claim 10 wherein,
the digitlines are individually electrically coupled to the individual another source/drain regions by conducting vias that are individually directly above and electrically coupled to the individual another source/drain regions; and
the islands of the first conductive material having a top that is below a bottom of the digitlines and below a top of the conducting vias.

14. The method of claim 10 wherein the etching forms trenches that are individually directly above a plurality of the another source/drain regions and above and crossing over the plurality of conductive-gate lines.

15. The method of claim 14 wherein individual of the trenches are widest directly above the another source/drain regions than between the another source/drain regions.

16. The method of claim 15 comprising forming insulator material in the individual trenches that laterally-fills narrower portions of the individual trenches and does not laterally-fill widest portions of the trenches that are directly above the another source/drain regions.

17. The method of claim 6 wherein the second conductive material extends downwardly into the first conductive material.

18. The method of claim 6 wherein the second conductive material extends laterally-outward beyond the first conductive material.

19. The method of claim 6 wherein individual of the islands extend laterally-outward beyond the individual one source/drain regions.

20. Memory circuitry, comprising:
transistors individually comprising:
one source/drain region and another source/drain region;
a channel region between the one and the another source/drain regions; and
a conductive gate operatively proximate the channel region;
conducting vias that are individually directly above and electrically coupled to individual of the another source/drain regions;
digitlines that are individually above and directly electrically coupled to a plurality of the conducting vias;
conductive-via constructions that are individually directly above and directly against individual of the one source/drain regions, individual of the conductive-via constructions comprising:
islands of first conductive material that are individually directly above and directly against the individual one source/drain regions, the islands of the first conductive material having a top that is below a bottom of the digitlines and below a top of the conducting vias; and
second conductive material directly above and directly against the islands of the first conductive material; and
storage elements that are individually electrically coupled to the individual conductive-via construction.
